(19) United States
(12) Patent Application Publication
(10) Pub. No.: US 2023/0005410 A1
(43) Pub. Date: Jan. 5, 2023

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xinyu WEI, Beijing (CN); Kai ZHANG, Beijing (CN); Yonglin GUO, Beijing (CN); Yunsheng XIAO, Beijing (CN); Miao WANG, Beijing (CN); Hongmei FAN, Beijing (CN)

(21) Appl. No.: 17/778,606

(22) PCT Filed: Jan. 13, 2021
(86) PCT No.: PCT/CN2021/071552

§ 371 Date: May 20, 2022

(30) Foreign Application Priority Data
Jan. 21, 2020 (CN) 202010072398.5

(51) Int. Cl. G09G 3/20; G11C 19/28

(52) U.S. Cl. CPC G09G 3/2092; G11C 19/28; G09G 2310/0286; G09G 2300/0426; G09G 2320/0233

(57) ABSTRACT

A display panel and a display device are provided. The display panel includes: a display region and a peripheral region surrounding the display region. The display region comprises a first display sub-region and a second display sub-region. The width-to-length ratio of a channel region of an output transistor in a second gate shift register corresponding to the second display sub-region is decreased so as to reduce the charging time of pixels in the second display sub-region, so that the brightness of the pixels in the second display sub-region is consistent with the brightness region of pixels in the first display sub-region. The configuration facilitates achieving a narrow bezel while improving the display uniformness of the display panel without changing the existing circuit structure and occupying the additional bezel area.

### CROSS REFERENCE TO RELATED APPLICATIONS

The present disclosure is a national phase entry under 35 U.S.C § 371 of International Application No. PCT/CN2021/071552, filed Jan. 13, 2021, which claims priority to the Chinese Patent Application No. 202010072398.5, entitled “DISPLAY PANEL AND DISPLAY DEVICE”, filed to the China National Intellectual Property Administration on Jan. 21, 2020, the entire contents of which are incorporated herein by reference.

### FIELD

The present disclosure relates to the field of display, in particular to a display panel and a display device.

### BACKGROUND

With the development of a display technology, people have higher and higher requirements for display devices. In order to meet some functional requirements of the display devices, some special-shaped regions may be arranged on a display panel, such as a groove of a region where a front camera is located, or a chamfer at an edge of the display panel. The existence of the special-shaped region leads to a difference between the quantity of pixels connected to writing gate lines corresponding to the special-shaped region and the quantity of pixels connected to writing gate lines corresponding to a normal region, that is, a load of the writing gate lines corresponding to the special-shaped region is smaller than a load of the writing gate lines of the normal region, and consequently, the display uniformness of each region of the display panel is poor.

In the related art, in order to increase the load of the writing gate lines corresponding to the special-shaped region, a compensation capacitor can be arranged to be electrically connected to the writing gate lines, however, the compensation capacitor needs to occupy a large area, that is, a bezel region of the display panel is increased, which is not conductive to the narrow bezel design of the display panel.

Therefore, how to improve the display uniformness of the display panel while achieving a narrow bezel is an urgent technical problem for those skilled in the art.

### SUMMARY

In view of this, embodiments of the present disclosure provide a display panel and a display device, and the specific solutions are as follows.

In one aspect, the embodiment of the present disclosure provide a display panel, the display panel includes a display region and a peripheral region surrounding the display region, and the display region includes a first display sub-region and a second display sub-region;

the display region includes a plurality of rows of pixels and writing gate lines electrically connected to each of the plurality of rows of pixels correspondingly; the pixels include pixel circuits and light-emitting devices, the pixel circuits are electrically connected to the writing gate lines, and the pixel circuits are configured to receive data signals under control of the writing gate lines, and drive the light-emitting devices to emit light according to the received data signals;

a quantity of pixels in one row of pixels in the second display sub-region is smaller than a quantity of pixels in one row of pixels in the first display sub-region;

the peripheral region includes a gate shift register electrically connected to each of the writing gate lines correspondingly, the gate shift register includes an output transistor, a source electrode of the output transistor is electrically connected to a clock signal line, a drain electrode of the output transistor is electrically connected to a corresponding writing gate line, and the output transistor is configured to output a valid pulse signal to the corresponding writing gate line;

the gate shift register electrically connected to the writing gate line in the first display sub-region correspondingly is a first gate shift register, and the gate shift register electrically connected to the writing gate line in the second display sub-region correspondingly is a second gate shift register; and a width-to-length ratio of a channel region of an output transistor in the second gate shift register is smaller than a width-to-length ratio of a channel region of an output transistor in the first gate shift register.

In a possible implementation, in the display panel provided by the embodiments of the present disclosure, a length of the channel region of the output transistor in the second gate shift register is equal to a length of the channel region of the output transistor in the first gate shift register; and a width of the channel region of the output transistor in the second gate shift register is smaller than a width of the channel region of the output transistor in the first gate shift register.

In a possible implementation, in the display panel provided by the embodiments of the present disclosure, a width of the channel region of the output transistor in the second gate shift register is equal to a width of the channel region of the output transistor in the first gate shift register; and a length of the channel region of the output transistor in the second gate shift register is greater than a length of the channel region of the output transistor in the first gate shift register.

In a possible implementation, in the display panel provided by the embodiments of the present disclosure, the width-to-length ratio of the channel region of the output transistor in the second gate shift register is 20%-50% of the width-to-length ratio of the channel region of the output transistor in the first gate shift register.

In a possible implementation, in the display panel provided by the embodiments of the present disclosure, the second display sub-region, in an extending direction of the writing gate lines, includes: a first region, a second region and an intermediate region, and the first region and the second region are separated by the intermediate region; and only the first region and the second region include the plurality of rows of pixels.

In a possible implementation, in the display panel provided by the embodiments of the present disclosure, the intermediate region is in a groove shape, and an opening side of the groove shape is arranged very close to a first boundary of the display panel.

In a possible implementation, in the display panel provided by the embodiments of the present disclosure, a length of a side, close to the opening side, of the intermediate region in the extending direction of the writing gate lines is greater than a length of a side, away from the opening side, of the intermediate region away from the opening in the extending direction of the writing gate lines.

In a possible implementation, in the display panel provided by the embodiments of the present disclosure, a width-to-length ratio of a channel region of an output transistor in a second gate shift register close to the first boundary is smaller than a width-to-length ratio of a channel region of an output transistor in a second gate shift register away from the first boundary.

In a possible implementation, in the display panel provided by the embodiments of the present disclosure, the writing gate lines in the first region and the writing gate lines in the second region are disconnected in the intermediate region, and each disconnected writing gate line is connected to a second gate shift register.

In a possible implementation, in the display panel provided by the embodiments of the present disclosure, at least part of edges of the first region, the second region and the intermediate region are a curved edge, a rounded corner, a chamfer or a notch; and each row of pixels in the first region and the second region extends to the curved edge, the rounded corner, the chamfer or the notch.

In another aspect, an embodiment of the present disclosure further provides a display device, including the display panel provided by any one of the embodiments.

### BRIEF DESCRIPTION OF THE DRAWINGS

FIG. 1 is a first schematic structural diagram of a display panel provided by an embodiment of the present disclosure.

FIG. 2 is a second schematic structural diagram of a display panel provided by an embodiment of the present disclosure.

FIG. 3 is a first schematic structural diagram of a pixel circuit provided by an embodiment of the present disclosure.

FIG. 4 is a second schematic structural diagram of a pixel circuit provided by an embodiment of the present disclosure.

FIG. 5 is a schematic structural diagram of a gate shift register provided by an embodiment of the present disclosure.

FIG. 6 is a timing diagram corresponding to the gate shift register shown in FIG. 5.

FIG. 7 is a schematic top view of an output transistor provided by an embodiment of the present disclosure.

FIG. 8 is a schematic structural diagram of a size of a channel region of an output transistor provided by an embodiment of the present disclosure.

FIG. 9 is a schematic structural diagram of a second display sub-region provided by an embodiment of the present disclosure.

### DETAILED DESCRIPTION OF THE EMBODIMENTS

A display panel in the related art has a special-shaped region, the special-shaped region may be a groove/hole of a region where a front camera is located, or a chamfer at an edge of the display panel. The existence of the special-shaped region causes the quantity of pixels connected to a row of gate lines of the special-shaped region to be smaller than the quantity of pixels connected to a row of gate lines of a normal region, that is, a load of the gate lines of the special-shaped region is smaller than a load of the gate lines of the normal region, leading to the poor display uniformness of each region of the display panel.

In the related art, in order to increase the load of the gate lines of the special-shaped region, a compensation capacitor will be arranged to be electrically connected to the gate lines of the special-shaped region, however, the compensation capacitor needs to occupy a large area, that is, a bezel region of the display panel is increased, which is not conductive to the narrow bezel design of the display panel.

Based on the above problems of the display panel existing in the related art, embodiments of the present disclosure provide a display panel and a display device. In order to make the purpose, technical solutions and advantages of the present disclosure clearer, the specific implementations of the display panel and the display device provided by the embodiments of the present disclosure will be described in detail below with reference to the accompanying drawings. It should be understood that the preferred embodiments described below are only used to illustrate and explain the present disclosure and are not used to limit the present disclosure. Moreover, without conflict, the embodiments in the present disclosure and the features in the embodiments can be combined with each other.

Unless otherwise defined, technical or scientific terms used herein should have the ordinary meaning as understood by one of ordinary skill in the art to which this application belongs. The terms “first”, “second” and the like used in the present disclosure do not denote any order, quantity or importance, but are only used to distinguish different components. “Comprise” or “include” and similar words mean that the elements or objects appearing before the word encompass the elements or objects recited after the word and their equivalents, but do not exclude other elements or objects. Similar words such as “connect” or “link” are not limited to physical or mechanical connection, but may include electrical connection, whether direct or indirect. “Up”, “down”, “left”, “right” and the like are only used to indicate the relative positional relationship, and when the absolute position of a described object changes, the relative positional relationship may also change accordingly.

The shapes and sizes of various components in the accompanying drawings do not reflect the true ratio, and are only intended to illustrate the content of the present disclosure schematically.

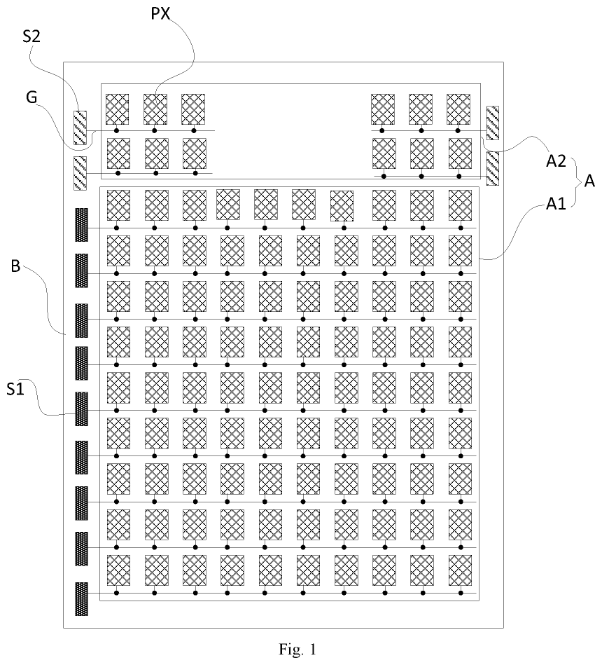

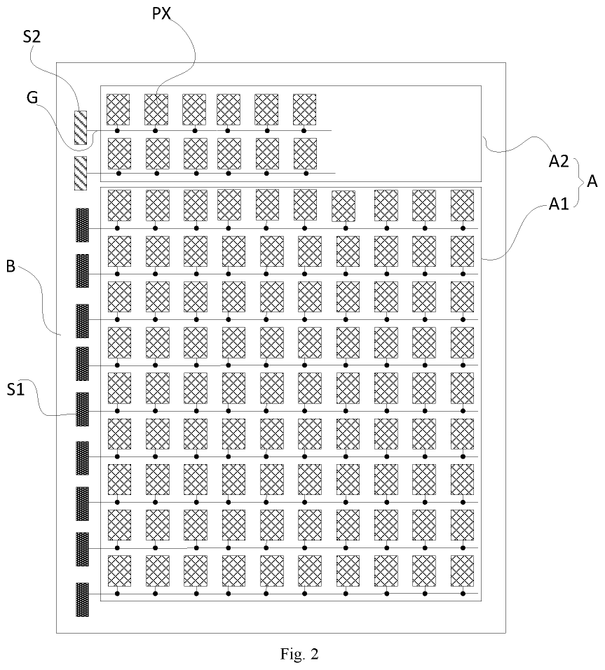

The embodiment of the present disclosure provides a display panel, as shown in FIG. 1 and FIG. 2, the display panel includes: a display region A and a peripheral region B surrounding the display region A, and the display region A includes a first display sub-region A1 and a second display sub-region A2. The display region A includes a plurality of rows of pixels PX and writing gate lines G electrically connected to each of the plurality of rows of pixels correspondingly. A quantity of pixels in one row of pixels PX in the second display sub-region A2 is smaller than a quantity of pixels in one row of pixels PX in the first display sub-region A1. The peripheral region B includes: a gate shift register S1 or S2 electrically connected to each of the writing gate lines G correspondingly (the specific structure of the gate shift register is not shown in FIG. 1 and FIG. 2).

In the present disclosure, since the quantity of the pixels in the row of pixels PX in the second display sub-region A2 is smaller than the quantity of the pixels in the row of pixels PX in the first display sub-region A1, a load of each of the writing gate lines G in the second display sub-region A2 is smaller than a load of each of the writing gate lines G in the first display sub-region A1. If compensation is not made, charging time of each pixel in the second display sub-region will be long, and consequently, brightness of the pixels in the first display sub-region and the second display sub-region is inconsistent.

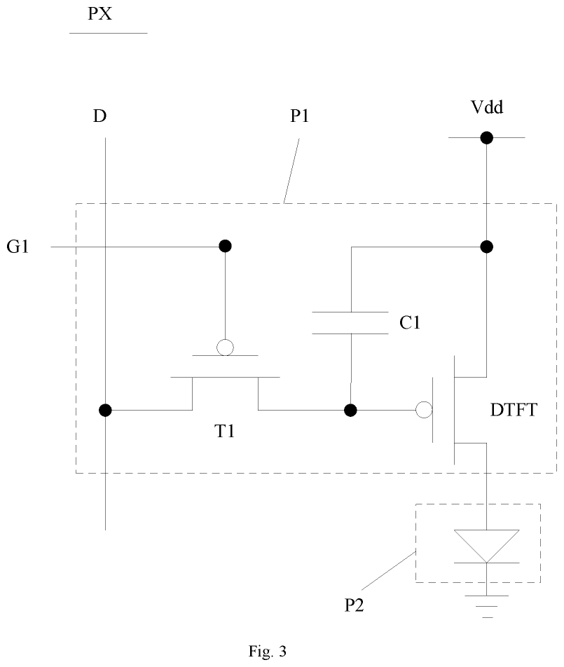

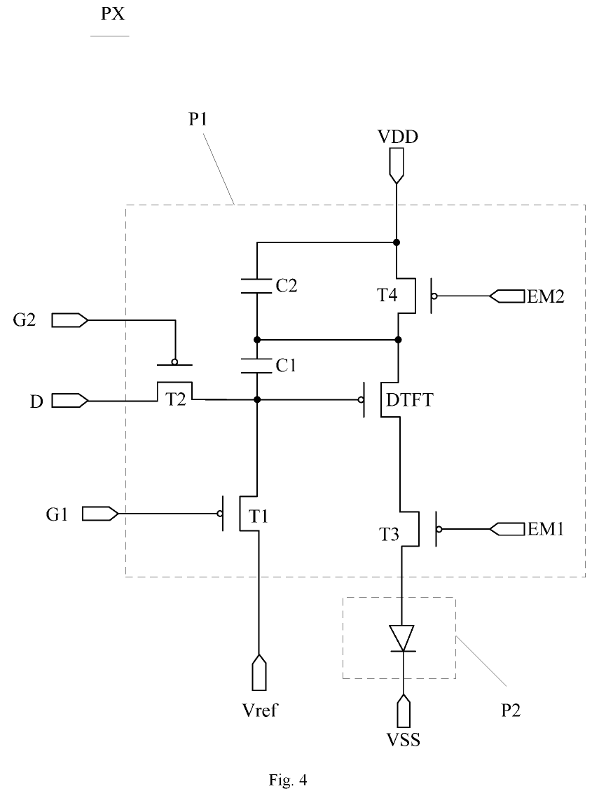

Referring to FIG. 3 and FIG. 4, the pixels PX include pixel circuits P1 and light-emitting devices P2, the pixel circuits P1 are electrically connected to the writing gate lines G, the pixel circuits P1 are configured to receive data signals under the control of the writing gate lines G, and drive the light-emitting devices P2 to emit light according to the received data signals.

The specific structure of the pixel circuits is not limited by the present disclosure, may be any structure that can achieve the above functions, such as a traditional pixel circuit shown in FIG. 3, and may further be any pixel circuit with a compensation effect, such as a pixel circuit shown in FIG. 4. Taking the pixel circuit shown in FIG. 3 and FIG. 4 as an example, referring to FIG. 3, the pixel circuit P1 includes a driving transistor DTFT, a switching transistor T1 and a capacitor C1, and the switching transistor T1 receives a data signal D under the control of the gate line G. Referring to FIG. 4, the pixel circuit P1 includes a driving transistor DTFT, switching transistors T1-T4 and capacitors C1 and C2, and the switching transistor T2 receives the data signal D under the control of the gate line G2. The driving transistor DTFT drives the light-emitting devices P1 to emit light according to the received data signal D. A driving current I=K(V_{GS}−Vₜₕ)²=K(V_{G}−V_{S}−Vₜₕ) Vₜₕ is a threshold voltage of the driving transistor DTFT, V_{S} is a source electrode voltage of the driving transistor DTFT, V_{G} is a gate voltage of the driving transistor DTFT, and magnitude of V_{G} is related to the charging time under the condition that the data signal D is fixed. Therefore, when the charging time of each pixel in the first display sub-region and the second display sub-region is inconsistent, the driving currents of the pixels in the first display sub-region and the second display sub-region will be inconsistent, and consequently, the brightness of the pixels in the first display sub-region and the second display sub-region is inconsistent.

In order to make the charging time of the pixels in the first display sub-region and the second display sub-region consistent, as shown in FIG. 1 and FIG. 2, in the present disclosure, the gate shift register electrically connected to the writing gate line G in the first display sub-region A1 correspondingly is a first gate shift register S1, the gate shift register electrically connected to the writing gate line G in the second display sub-region A2 correspondingly is a second gate shift register S2, and a width-to-length ratio of a channel region of an output transistor T5 in the second gate shift register S2 is smaller than a width-to-length ratio of a channel region of the output transistor in the first gate shift register S1.

The gate shift register includes an output transistor, a source electrode of the output transistor is electrically connected to a corresponding clock signal line, a drain electrode of the output transistor is electrically connected to the corresponding writing gate line, and the output transistor is configured to output a valid pulse signal to the corresponding writing gate line. Specifically, the gate shift register may output a pulse signal to the corresponding writing gate line, and only the valid pulse signal can control the pixel circuits to receive the data signal. Taking the pixel circuit of FIG. 3 and FIG. 4 as an example, if the switching transistor T1 of FIG. 3 is a P-type switching transistor, the valid pulse signals on the writing gate lines are low-potential signals, if the switching transistor T1 of FIG. 3 is an N-type switching transistor, the valid pulse signals on the writing gate lines are high-potential signals, if the switching transistor T2 of FIG. 4 is the P-type switching transistor, the valid pulse signals on the writing gate lines are the low-potential signals, and if the switching transistor T2 of FIG. 4 is the N-type switching transistor, the valid pulse signals on the writing gate lines are the high-potential signals.

The valid pulse signals output by the gate shift register are output by the output transistor, therefore, the performance of the output transistor can determine the valid pulse signals on the writing gate lines. In the present disclosure, a width-to-length ratio of the channel region of an output transistor in the second gate shift register is smaller than a width-to-length ratio of the channel region of an output transistor in the first gate shift register, that is, by reducing the width-to-length ratio of the channel region of the output transistor in the second gate shift register, an on-resistance of the output transistor in the second gate shift register can be increased, RC delay is increased, so that time of rising edge (Tr) and falling edge (TO of the output valid pulse signals is prolonged, then the charging time of each pixel circuit in the second display sub-region is shortened, the difference between the driving currents of each pixel in the second display sub-region and the driving currents of each pixel in the first display sub-region is reduced, and thus the brightness of each pixel in the second display sub-region is consistent with a brightness region of each pixel in the first display sub-region. The configuration facilitates achieving a narrow bezel while improving the display uniformness of the display panel without changing the existing circuit structure and occupying the additional bezel area.

It should be noted that in this application, the gate lines configured to control to receive the data signals D are the writing gate lines G, for example, a gate line G1 connected to a gate of the switching transistor T1 in FIG. 3 is a writing gate line, and a gate line G2 connected to a gate of the switching transistor T2 in FIG. 4 is a writing gate line. Although there are EM1, EM2 and G1 in FIG. 4, these are not the writing gate lines. In the present disclosure, the writing gate lines corresponding to the pixel circuits are the gate lines configured to control the pixel circuits to receive the data signals.

It should be also noted that there is a cascade relationship (not specifically shown in the figure) between the first gate shift registers and the second gate shifts register shown in FIG. 1 and FIG. 2, and the cascade relationship is the same as that between adjacent gate shift registers in the related art, which is not specifically limited here.

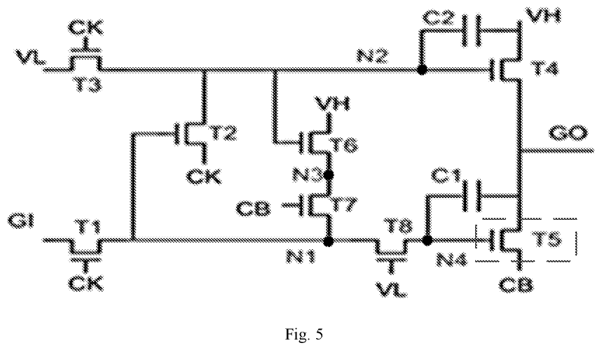

The structure of the gate shift registers is not limited by the present disclosure. Taking the structure of the gate shift register shown in FIG. 5 as an example, in addition to the output transistor T5 and a clock signal end CB, the gate shift register further includes: a transistor T1, a transistor T2, a transistor T3, a transistor T4, a transistor T6, a transistor T7, a transistor T8, a capacitor C1 and a capacitor C2, and further includes a signal end GI, a signal end VL, a signal end VH, a clock signal end CK and an output signal end GO which are configured to provide signals. The output signal end GO is electrically connected to the corresponding writing gate line in the display region. In addition, it further includes connection nodes among the transistors, such as a node N1, a node N2, a node N3 and a node N4. A working process of the shift register shown in FIG. 5 is the same as a working process of the shift register in the related art, which will not be repeated here.

FIG. 5 only illustrates a connection relationship of the output transistors by taking the structure of one gate shift register, and does not specifically limit the structures of the first gate shift register and the second gate shift register. The first gate shift register and the second gate shift register may be of the structure shown in FIG. 5, or the structure of any other gate shift register. Moreover, the structure of the first gate shift register and the second gate shift register may be the same or different, as long as the output transistors included in them comply with the above principle, which is not specifically limited here.

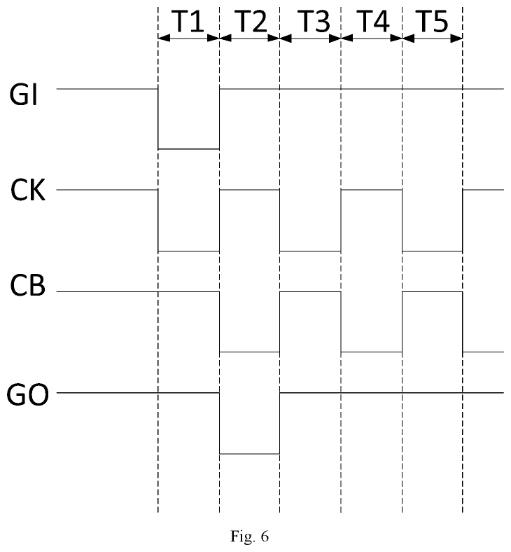

The gate shift register shown in FIG. 5 may be driven by the timing diagram shown in FIG. 6, and the timing diagram includes five driving stages (i.e. T1, T2, T3, T4 and T5). In the corresponding stages, corresponding driving signals are provided to the signal ends (GI, CK and CB) corresponding to the shift registers, so as to enable the output signal end GO to provide gate driving signals to the corresponding writing gate lines. Of course, the timing diagram shown in FIG. 6 is only one driving mode of the shift register shown in FIG. 5, other timing modes may also be used for driving and selected according to actual needs, which is not specifically limited here.

It should be noted that in the display panel provided by the embodiments of the present disclosure, an arrangement mode of the pixels in the second display sub-region may be as shown in FIG. 1, namely the pixels PX in a same row are electrically connected to different writing gate lines G, or as shown in FIG. 2, namely the pixels PX in the same row are electrically connected to the same writing gate line G, which is not specifically limited here. Moreover, the position of a groove region in the second display sub-region may be determined according to actual design needs, which is not limited to the two forms shown in FIG. 1 and FIG. 2, but also any other position or shape, which is not specifically limited here.

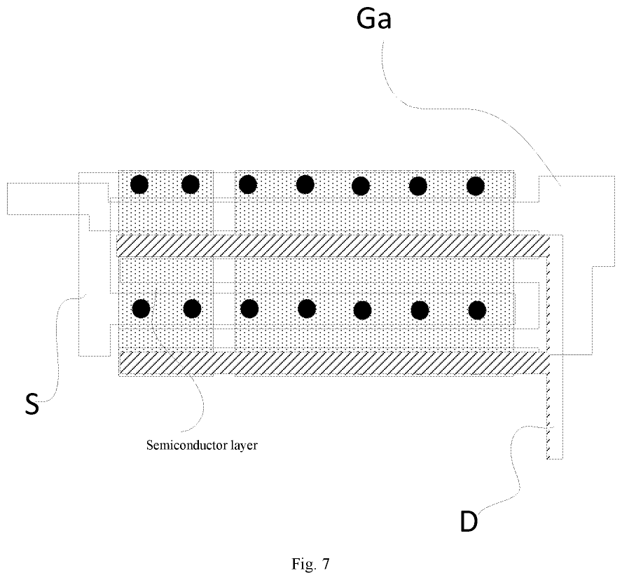

FIG. 7 is a schematic top view of an output transistor provided by the embodiments of the present disclosure, which includes a semiconductor layer Poly, a gate layer Ga located on the semiconductor layer Poly, and a source electrode S and a drain electrode D which are arranged on the gate layer Ga, and there is an insulating layer between the semiconductor layer Poly and a layer where the source electrode S and the drain electrode D are located, and between the gate layer Ga and the layer where the source electrode S and the drain electrode D are located. The source electrode S and the drain electrode D are electrically connected to the semiconductor layer Poly via through holes, and the semiconductor layer Poly includes a source doping region and a drain doping region.

A distance between the source doping region and the drain doping region in the transistor is called a length of the channel region, and a width of the channel region perpendicular to an extending direction of the channel region is called a channel width.

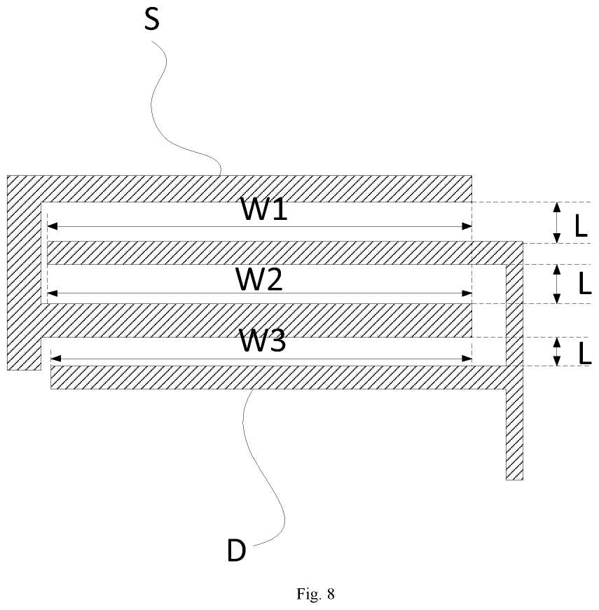

As shown in FIG. 8, the width of the channel region of the output transistor is W1+W2+W3, the length of the channel region of the output transistor is L, and the width-to-length ratio of the channel region of the output transistor is (W1+W2+W3)/L.

In the embodiments of the present disclosure, the width-to-length ratio of the channel region of the output transistor in the first gate shift register and the width-to-length ratio of the channel region of the output transistor in the second gate shift register can be adjusted, so that the display brightness of each pixel in the first display sub-region and the second display sub-region tends to be consistent. There are two specific adjusting modes as follows.

A total width of the channel region of the output transistor in the first gate shift register is WA=W1+W2+W3, and a value of WA may be adjusted by adjusting the size of W1, W2 and/or W3; the length of the channel region of the output transistor in the first gate shift register is LA=L, and a value of LA may be adjusted by adjusting the size of L.

Similarly, a total width of the channel region of the output transistor in the second gate shift register is WB=W1+W2+W3, a value of WB may be adjusted by adjusting the size of W1, W2 and/or W3; and the length of the channel region of the output transistor in the second gate shift register LB=L, and a value of LB may be adjusted by adjusting the size of L.

One of the adjusting modes is: the length LB of the channel region of the output transistor in the second gate shift register is equal to the length LA of the channel region of the output transistor in the first gate shift register; and the width WB of the channel region of the output transistor in the second gate shift register is smaller than the width WA of the channel region of the output transistor in the first gate shift register.

In the display panel provided by the embodiments of the present disclosure, the smaller the width-to-length ratio of the channel region of the output transistor, the longer the time of rising edge and falling edge that the output transistor provides to the signals of the corresponding writing gate lines, so as to shorten the charging time of the pixel circuits to reduce the difference of the driving currents of the pixel circuits, and thus the brightness of the light-emitting devices in the first display sub-region and the second display sub-region is consistent.

Therefore, in order to reduce the charging time of each pixel circuit in the second display sub-region, it is necessary to make the width-to-length ratio WB/LB of the channel region of the output transistor in the second gate shift register smaller than the width-to-length ratio WA/LA of the channel region of the output transistor in the first gate shift register. When LB is equal to LA, WB<WA may be made, so that WB/LB<WA/LA.

The other adjusting mode is: the width WB of the channel region of the output transistor in the second gate shift register is equal to the width WA of the channel region of the output transistor in the first gate shift register; and the length LB of the channel region of the output transistor in the second gate shift register is greater than the length LA of the channel region of the output transistor in the first gate shift register.

In the display panel provided by the embodiments of the present disclosure, the smaller the width-to-length ratio of the channel region of the output transistor, the longer the time of rising edge and falling edge that the output transistor provides to the signals of the corresponding writing gate lines, so as to shorten the charging time of the pixel circuits to reduce the difference of the driving currents of the pixel circuits, and thus the brightness of the light-emitting devices in the first display sub-region and the second display sub-region is consistent.

Therefore, in order to reduce the charging time of each pixel circuit in the second display sub-region, it is necessary to make the width-to-length ratio WB/LB of the channel region of the output transistor in the second gate shift register smaller than the width-to-length ratio WA/LA of the channel region of the output transistor in the first gate shift register. When WB is equal to WA, LB>LA may be made, so that WB/LB<WA/LA.

It should be noted that FIG. 7 and FIG. 8 only illustrate the structure of the output transistor provided by the embodiments of the present disclosure schematically, the output transistor is not only limited to the structure shown in FIG. 7 and FIG. 8, and may further be other output transistor in accordance with the implementation principle of the present disclosure, which is not specifically limited here.

Optionally, in the display panel provided by the embodiments of the present disclosure, the width-to-length ratio of the channel region of the output transistor in the second gate shift register is 20%-50% of the width-to-length ratio of the channel region of the output transistor in the first gate shift register.

In the display panel provided by the embodiments of the present disclosure, when the width-to-length ratio of the channel region of the output transistor in the second gate shift register is 50% of the width-to-length ratio of the channel region of the output transistor in the first gate shift register, the time of rising edge provided by the second gate shift register to the driving signals of the writing gate lines is increased by 2.29%, and the time of falling edge is increased by 7.39%; and when the width-to-length ratio of the channel region of the output transistor in the second gate shift register is 20% of the width-to-length ratio of the channel region of the output transistor in the first gate shift register, the time of rising edge provided by the second gate shift register to the driving signals of the writing gate lines is increased by 5.14%, and the time of falling edge is increased by 18.16%. Since the overall time of the driving signals is certain, the time of rising edge and the time of falling edge are increased, which inevitably leads to the decrease of the charging time of the pixels, and the greater the percentage of the increase of the time of rising edge and the time of falling edge, the greater the percentage of the decrease of the charging time.

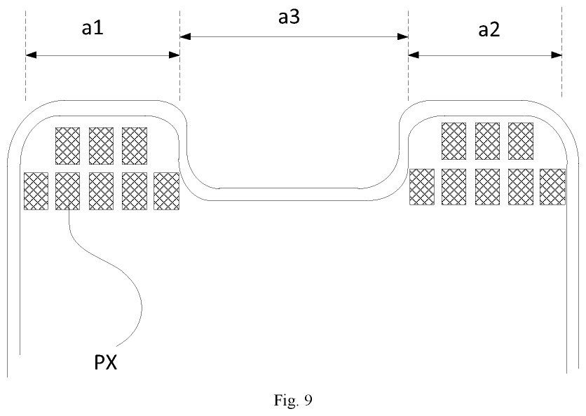

Optionally, in the display panel provided by the embodiments of the present disclosure, as shown in FIG. 9, the second display sub-region, in an extending direction of the writing gate lines, includes: a first region a1, a second region a2 and an intermediate region a3, and the first region a1 and the second region a2 are separated by the intermediate region a3; and only the first region a1 and the second region a2 include the plurality of rows of pixels.

In one embodiment, in the display panel provided by the embodiments of the present disclosure, as shown in FIG. 9, the second display sub-region is divided into three regions by the intermediate region, the plurality of rows of pixels are arranged in the first region and the second region respectively, and the pixels are not arranged in the intermediate region, a groove may be arranged in the intermediate region and configured to hold devices such as a front camera, a photosensitive element and an earpiece, and thus the display device has other functions besides display.

Optionally, in the display panel provided by the embodiments of the present disclosure, the intermediate region is in a groove shape, and an opening side of the groove shape is arranged very close to a first boundary of the display panel.

Exemplarily, in the display panel provided by the embodiments of the present disclosure, the intermediate region may be in the groove shape, and arranged very close to one boundary of the display panel. FIG. 9 takes the situation that the intermediate region is very close to an upper boundary (i.e. the first boundary) of the display panel as an example for illustration, of course, the intermediate region may also be arranged in other regions of the display panel, which is not specifically limited here.

It should be noted that in the display panel provided by the embodiments of the present disclosure, in addition to the groove shape, the intermediate region may further be in closed shapes such as a rectangle, a circle, an ellipse or a polygon, which is not specifically limited here.

Optionally, in the display panel provided by the embodiments of the present disclosure, a length of a side, close to the opening side, of the intermediate region in the extending direction of the writing gate lines is greater than a length of a side, away from the opening side, of the intermediate region in the extending direction of the writing gate lines.

Exemplarily, in the display panel provided by the embodiments of the present disclosure, the intermediate region may be arranged as a region with different widths according to the arranged devices. When its width is small, the widths of the corresponding first region and second region are relatively large, and more pixels may be arranged in the first region and second region. When its width is large, the widths of the first region and the second region are relatively small, and less pixels are arranged in the first region and second region. For example, when the intermediate region is in the groove shape with a wide top and a narrow bottom, in the second display sub-region, a partial region, close to the upper boundary of the display panel, of the first region and the second region includes more pixels, and the other partial region, away from the upper boundary of the display panel, of the first region and the second region includes less pixels.

Based on the above, in order to achieve more precise brightness adjustment, the width-to-length ratio of the channel region of the output transistor in the second gate shift register close to the first boundary may be smaller than the width-to-length ratio of the channel region of the output transistor in the second gate shift register away from the first boundary, so that the display brightness region in each region of the display panel is uniform, and the display uniformness of the display panel is improved.

Optionally, in the display panel provided by the embodiments of the present disclosure, the writing gate lines in the first region and the writing gate lines in the second region are mutually disconnected in the intermediate region, and each disconnected writing gate line is connected to one second gate shift register.

Exemplarily, each pixel in the second display sub-region is arranged as the structure shown in FIG. 1, since the intermediate region has a groove, in order to simplify the design, a writing gate line in the first region may be disconnected from a writing gate line in the second region, and a second gate shift register connected with the writing gate line in the first region is arranged in the peripheral region corresponding to the first region, and a second gate shift register connected with the writing gate line in the second region is arranged in the peripheral region corresponding to the second region, so as to drive the pixels in the first region and the second region. Of course, the writing gate line in the first region and the writing gate line in the second region may also be electrically connected, so one second gate shift register can be arranged accordingly, but it will correspondingly increase the difficulty of design. The specific configuration may be selected according to the actual use condition, which is not specifically limited here.

Optionally, in the display panel provided by the embodiments of the present disclosure, as shown in FIG. 9, at least part of edges of the first region a1, the second region a2 and the intermediate region a3 are a curved edge, a rounded corner, a chamfer or a notch; and each row of pixels in the first region a1 and the second region a2 extends to the curved edge, the rounded corner, the chamfer or the notch.

Specifically, in the display panel provided by the embodiments of the present disclosure, as shown in FIG. 9, boundaries of the first region a1, the second region a2 and the intermediate region a3 all include the rounded corner or the chamfer, the arrangement of the rounded corner or the chamfer can also make the quantity of pixels of different rows in the second display sub-region have difference, the width-to-length ratio of the channel region of the output transistor in the corresponding second gate shift register may be adjusted to compensate the difference, so as to improve the display uniformness of each region.

Based on the same inventive concept, the embodiments of the present disclosure further provides a display device, the display device includes the display panel provided by any one of the above embodiments.

The display device may be any products or components with display functions such as a mobile phone, a tablet computer, a television, a monitor, a notebook computer, a digital photo frame and a navigator. Other essential components of the display device should be understood by those skilled in the art, and will not repeated herein, nor should it be used as a limitation of the present disclosure. The implementation of the display device may refer to the implementation of the above display panel, and the repetition will not be made.

The embodiments of the present disclosure provide the display panel and the display device. The display panel includes the display region and the peripheral region surrounding the display region, and the display region includes the first display sub-region and the second display sub-region; the display region includes the plurality of rows of pixels and the writing gate lines electrically connected to each of the plurality of rows of pixels correspondingly; the quantity of pixels in one row of pixels in the second display sub-region is smaller than the quantity of pixels in one row of pixels in the first display sub-region; the peripheral region includes the gate shift register electrically connected to each of the writing gate lines correspondingly, the gate shift register includes the output transistor, and the output transistor is configured to output a valid pulse signal to a corresponding writing gate line. The gate shift register electrically connected to the writing gate line in the first display sub-region correspondingly is the first gate shift register, and the gate shift register electrically connected to the writing gate line in the second display sub-region correspondingly is the second gate shift register; and the width-to-length ratio of the channel region of an output transistor in the second gate shift register is smaller than the width-to-length ratio of the channel region of an output transistor in the first gate shift register. In the embodiments of the present disclosure, the width-to-length ratio of the channel region of the output transistor in the second gate shift register corresponding to the second display sub-region is decreased so as to reduce the charging time of the pixels in the second display sub-region, so that the brightness of the pixels in the second display sub-region is consistent with the brightness region of the pixels in the first display sub-region. The configuration facilitates achieving the narrow bezel while improving the display uniformness of the display panel without changing the existing circuit structure and occupying the additional bezel area.

Obviously, those skilled in the art can make various modifications and variations to the present disclosure without departing from the spirit and scope of the present disclosure. As such, provided that these modifications and variations of the present disclosure fall within the scope of the claims of the present disclosure and their equivalents, the present disclosure is also intended to cover such modifications and variations.

1. A display panel, comprising:
a display region; and
a peripheral region surrounding the display region;
wherein the display region comprises a first display sub-region and a second display sub-region;
the display region comprises a plurality of rows of pixels and writing gate lines electrically connected to each of the plurality of rows of pixels correspondingly; the pixels comprise pixel circuits and light-emitting devices, wherein the pixel circuits are electrically connected to the writing gate lines, and the pixel circuits are configured to receive data signals under control of the writing gate lines, and drive the light-emitting devices to emit light according to the received data signals;
a quantity of pixels in one row of pixels in the second display sub-region is smaller than a quantity of pixels in one row of pixels in the first display sub-region;
the peripheral region comprises a gate shift register electrically connected to each of the writing gate lines correspondingly, the gate shift register comprises an output transistor, wherein a source electrode of the output transistor is electrically connected to a clock signal line, a drain electrode of the output transistor is electrically connected to a corresponding writing gate line, and the output transistor is configured to output a valid pulse signal to the corresponding writing gate line; wherein
the gate shift register electrically connected to the writing gate line in the first display sub-region correspondingly is a first gate shift register, and the gate shift register electrically connected to the writing gate line in the second display sub-region correspondingly is a second gate shift register; and a width-to-length ratio of a channel region of an output transistor in the second gate shift register is smaller than a width-to-length ratio of a channel region of an output transistor in the first gate shift register.

2. The display panel according to claim 1, wherein a length of the channel region of the output transistor in the second gate shift register is equal to a length of the channel region of the output transistor in the first gate shift register; and
a width of the channel region of the output transistor in the second gate shift register is smaller than a width of the channel region of the output transistor in the first gate shift register.

3. The display panel according to claim 1, wherein a width of the channel region of the output transistor in the second gate shift register is equal to a width of the channel region of the output transistor in the first gate shift register; and
a length of the channel region of the output transistor in the second gate shift register is greater than a length of the channel region of the output transistor in the first gate shift register.

4. The display panel according to claim 1, wherein the width-to-length ratio of the channel region of the output transistor in the second gate shift register is 20%-50% of the width-to-length ratio of the channel region of the output transistor in the first gate shift register.

5. The display panel according to claim 1, wherein the second display sub-region, in an extending direction of the writing gate lines, comprises: a first region, a second region and an intermediate region, and the first region and the second region are separated by the intermediate region; and
only the first region and the second region comprise the plurality of rows of pixels.

6. The display panel according to claim 5, wherein the intermediate region is in a groove shape, and an opening side of the groove shape is arranged close to a first boundary of the display panel.

7. The display panel according to claim 6, wherein a length of a side, close to the opening side, of the intermediate region in the extending direction of the writing gate lines is greater than a length of a side, away from the opening side, of the intermediate region in the extending direction of the writing gate lines.

8. The display panel according to claim 6, wherein a width-to-length ratio of a channel region of an output transistor in a second gate shift register close to the first boundary is smaller than a width-to-length ratio of a channel region of an output transistor in a second gate shift register away from the first boundary.

9. The display panel according to claim 5, wherein the writing gate lines in the first region and the writing gate lines in the second region are disconnected in the intermediate region, and each of the writing gate lines in the first region and each of the writing gate lines in the second region is connected to a corresponding second gate shift register respectively.

10. The display panel according to claim 5, wherein at least part of edges of the first region, the second region and the intermediate region are a curved edge, a rounded corner, a chamfer or a notch; and
each row of pixels in the first region and the second region extends to the curved edge, the rounded corner, the chamfer or the notch.

11. A display device, comprising a display panel; wherein the display panel comprises: a display region; and
a peripheral region surrounding the display region;
wherein the display region comprises a first display sub-region and a second display sub-region;
the display region comprises a plurality of rows of pixels and writing gate lines electrically connected to each of the plurality of rows of pixels correspondingly; the pixels comprise pixel circuits and light-emitting devices, wherein the pixel circuits are electrically connected to the writing gate lines, and the pixel circuits are configured to receive data signals under control of the writing gate lines, and drive the light-emitting devices to emit light according to the received data signals;
a quantity of pixels in one row of pixels in the second display sub-region is smaller than a quantity of pixels in one row of pixels in the first display sub-region;
the peripheral region comprises a gate shift register electrically connected to each of the writing gate lines correspondingly, the gate shift register comprises an output transistor, wherein a source electrode of the output transistor is electrically connected to a clock signal line, a drain electrode of the output transistor is electrically connected to a corresponding writing gate line, and the output transistor is configured to output a valid pulse signal to the corresponding writing gate line; wherein
the gate shift register electrically connected to the writing gate line in the first display sub-region correspondingly is a first gate shift register, and the gate shift register electrically connected to the writing gate line in the second display sub-region correspondingly is a second gate shift register; and a width-to-length ratio of a channel region of an output transistor in the second gate shift register is smaller than a width-to-length ratio of a channel region of an output transistor in the first gate shift register.

12. The display device according to claim 11, wherein a length of the channel region of the output transistor in the second gate shift register is equal to a length of the channel region of the output transistor in the first gate shift register; and
a width of the channel region of the output transistor in the second gate shift register is smaller than a width of the channel region of the output transistor in the first gate shift register.

13. The display device according to claim 11, wherein a width of the channel region of the output transistor in the second gate shift register is equal to a width of the channel region of the output transistor in the first gate shift register; and
a length of the channel region of the output transistor in the second gate shift register is greater than a length of the channel region of the output transistor in the first gate shift register.

14. The display device according to claim 11, wherein the width-to-length ratio of the channel region of the output transistor in the second gate shift register is 20%-50% of the width-to-length ratio of the channel region of the output transistor in the first gate shift register.

15. The display device according to claim 11, wherein the second display sub-region, in an extending direction of the writing gate lines, comprises: a first region, a second region and an intermediate region, and the first region and the second region are separated by the intermediate region; and
only the first region and the second region comprise the plurality of rows of pixels.

16. The display device according to claim 15, wherein the intermediate region is in a groove shape, and an opening side of the groove shape is arranged close to a first boundary of the display panel.

17. The display device according to claim 16, wherein a length of a side, close to the opening side, of the intermediate region in the extending direction of the writing gate lines is greater than a length of a side, away from the opening side, of the intermediate region in the extending direction of the writing gate lines.

18. The display device according to claim 16, wherein a width-to-length ratio of a channel region of an output transistor in a second gate shift register close to the first boundary is smaller than a width-to-length ratio of a channel region of an output transistor in a second gate shift register away from the first boundary.

19. The display device according to claim 15, wherein the writing gate lines in the first region and the writing gate lines in the second region are disconnected in the intermediate region, and each of the writing gate lines in the first region and each of the writing gate lines in the second region is connected to a corresponding second gate shift register respectively.

20. The display device according to claim 15, wherein at least part of edges of the first region, the second region and the intermediate region are a curved edge, a rounded corner, a chamfer or a notch; and
each row of pixels in the first region and the second region extends to the curved edge, the rounded corner, the chamfer or the notch.
